(19) United States
(12) Patent Application Publication
(10) Pub. No.: US 2012/0193136 A1
(43) Pub. Date: Aug. 2, 2012

(54) Folding Methods for Making Frames of Board Level Electromagnetic Interference (EMI) Shields

(75) Inventors: Igor Vinokur, Skokie, IL (US); Gerald R. English, Glen Ellyn, IL (US); Zbigniew M. Korus, Palatine, IL (US)

(73) Assignee: LAIRD TECHNOLOGIES, INC., Chesterfield, MO (US)

(21) Appl. No.: 13/017,967

(22) Filed: Jan. 31, 2011

(51) Int. Cl. H05K 9/00; H05K 13/00

(52) U.S. Cl. 174/377; 29/592.1

(57) ABSTRACT

Disclosed herein are exemplary embodiments of methods of making frames for electromagnetic (EMI) shielding apparatus. An exemplary method generally includes forming a frame to have at least a first frame portion, a second frame portion, and a common sidewall including at least a portion shared by and connecting the first and second frame portions. The second frame portion is repositioned from being disposed within a footprint of the first frame portion to outside the footprint of the first frame portion. Another exemplary embodiment includes a frame having first and second frame portions. The second frame portion is of a size sufficient to fit within an interior region defined by the first frame portion. The first and second frame portions share at least a portion of a common sidewall having a bendable hinge portion that connects the second frame portion to the first frame portion.

### FIELD

The present disclosure generally relates to shields suitable for shielding components on a printed circuit board from electromagnetic interference (EMI)/radio frequency interference (RFI).

### BACKGROUND

This section provides background information related to the present disclosure which is not necessarily prior art.

Electronic equipment often generates electromagnetic signals in one portion of the electronic equipment that may radiate to and interfere with another portion of the electronic equipment. This electromagnetic interference (EMI) can cause degradation or complete loss of important signals, thereby rendering the electronic equipment inefficient or inoperable. To reduce the adverse effects of EMI, electrically conducting (and sometimes magnetically conducting) material is interposed between the two portions of the electronic circuitry for absorbing and/or reflecting EMI energy. This shielding may take the form of a wall or a complete enclosure and may be placed around the portion of the electronic circuit generating the electromagnetic signal and/or may be placed around the portion of the electronic circuit that is susceptible to the electromagnetic signal. For example, electronic circuits or components of a printed circuit board (PCB) are often enclosed with shields to localize EMI within its source, and to insulate other devices proximal to the EMI source.

As used herein, the term electromagnetic interference (EMI) should be considered to generally include and refer to both electromagnetic interference (EMI) and radio frequency interference (RFI) emissions, and the term “electromagnetic” should be considered to generally include and refer to both electromagnetic and radio frequency from external sources and internal sources. Accordingly, the term shielding (as used herein) generally includes and refers to both EMI shielding and RFI shielding, for example, to prevent (or at least reduce) ingress and egress of EMI and RFI relative to a housing or other enclosure in which electronic equipment is disposed.

### SUMMARY

This section provides a general summary of the disclosure, and is not a comprehensive disclosure of its full scope or all of its features.

Disclosed herein are exemplary embodiments of frames for EMI shielding apparatus and methods for making such frames. Other aspects of the present disclosure relate to EMI shielding apparatus that include such frames and covers or lids attachable thereto, where the EMI shielding apparatus may be used for providing electromagnetic interference (EMI) shielding for one or more components on a substrate. Further aspects of the present disclosure relate to methods of providing EMI shielding.

In an example embodiment, a method generally includes forming a frame to have at least a first frame portion, a second frame portion, and a common sidewall including at least a portion shared by and connecting the first and second frame portions. The second frame portion is repositioned from being disposed within a footprint of the first frame portion to outside the footprint of the first frame portion.

Another exemplary embodiment includes a method relating to providing electromagnetic interference (EMI) shielding for one or more components on a substrate. In this example, the method generally includes forming a piece of material having a first frame portion and a second frame portion initially disposed within a footprint of the first frame portion with a common sidewall portion shared by and connecting the first and second frame portions. The second frame portion is repositioned outside the footprint of the first frame portion. The method may also include attaching at least one cover to at least one of the first and second frame portions.

Another exemplary embodiment includes a frame for an EMI shielding apparatus for use in providing EMI shielding for one or more components on a substrate. In this exemplary embodiment, the frame generally includes first and second frame portions. The first frame portion has a plurality of sidewalls that at least partially surround an interior region of the first frame portion. The second frame portion is of a size sufficient to fit within the interior region defined by the first frame portion. The second frame portion has a plurality of sidewalls. The first and second frame portions share at least a portion of a common sidewall having a bendable hinge portion that connects the second frame portion to the first frame portion.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of a conventional frame having first and second frame portions made from a flat piece of material;

FIG. 2 is an enlarged view of a portion of the conventional frame shown in FIG. 1;

FIG. 3 is a plan view of a flat piece of material having a profile from which the conventional frame shown in FIG. 1 is formed;

FIG. 4 is a perspective view of a frame for an EMI shield, according to an exemplary embodiment of the present disclosure;

FIG. 5 illustrates a method for forming a frame for an EMI shield, according to an exemplary embodiment of the present disclosure;

FIG. 6 is a perspective view of a flat piece of material having a profile from which the frame shown in FIG. 5 may be formed;

FIG. 7 is a perspective view of a frame having a common sidewall formed according to the method illustrated in FIG. 5;

FIG. 8 is an enlarged view of a portion of the frame shown in FIG. 7;

FIG. 9 is a perspective view of a flat piece of material having a profile for telescopic folding into a frame according to another exemplary embodiment of the present disclosure;

FIG. 10 is a perspective view of a frame made from the flat piece of material having the profile shown in FIG. 9;

FIG. 11 is another perspective view of the frame shown in FIG. 10;

FIG. 12 is a perspective view of another exemplary frame formed according to the method illustrated in FIG. 5;

FIG. 13 is a top plan view of the frame shown in FIG. 12;

FIG. 14 is a left elevation view of the frame shown in FIG. 12;

FIG. 15 is a right elevation view of the frame shown in FIG. 12;

FIG. 16 is a back elevation view of the frame shown in FIG. 12;

FIG. 17 is a front elevation view of the frame shown in FIG. 12;

FIG. 18 is a perspective view of a flat piece of material having a profile for forming another frame, according to another exemplary embodiment of the present disclosure;

FIG. 19 is a perspective view of a frame made from the flat piece of material having the profile shown in FIG. 18;

FIG. 20 is an exploded perspective view of a frame and cover of an EMI shielding apparatus according to an exemplary embodiment of the present disclosure;

FIG. 21 is a cutaway view of the EMI shielding apparatus shown in FIG. 20 with the cover attached to the frame; and

FIG. 22 is an exploded perspective view of a frame and two covers of an EMI shielding apparatus according to another exemplary embodiment of the present disclosure.

Corresponding reference numerals indicate corresponding parts throughout the several views of the drawings.

### DETAILED DESCRIPTION

Example embodiments will now be described more fully with reference to the accompanying drawings.

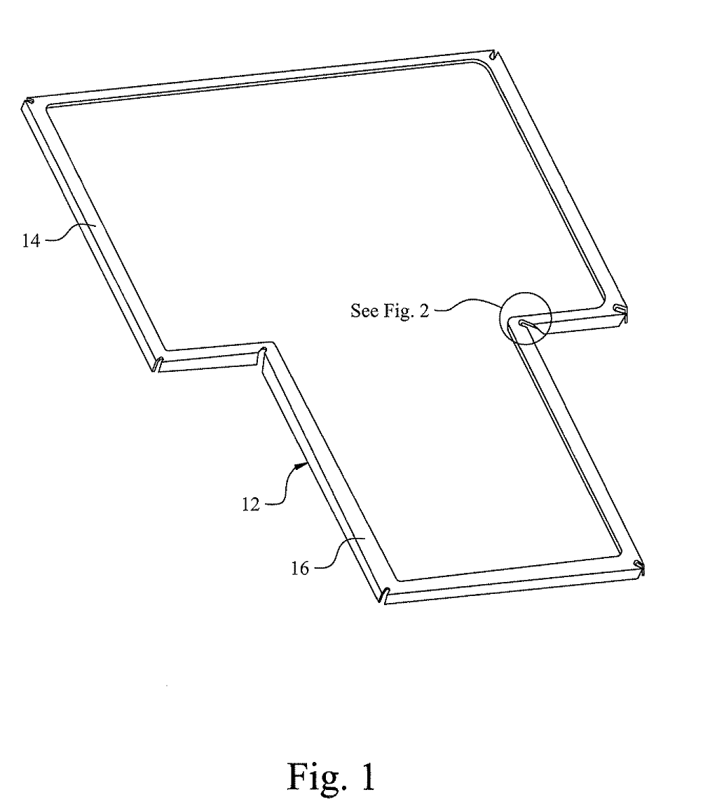

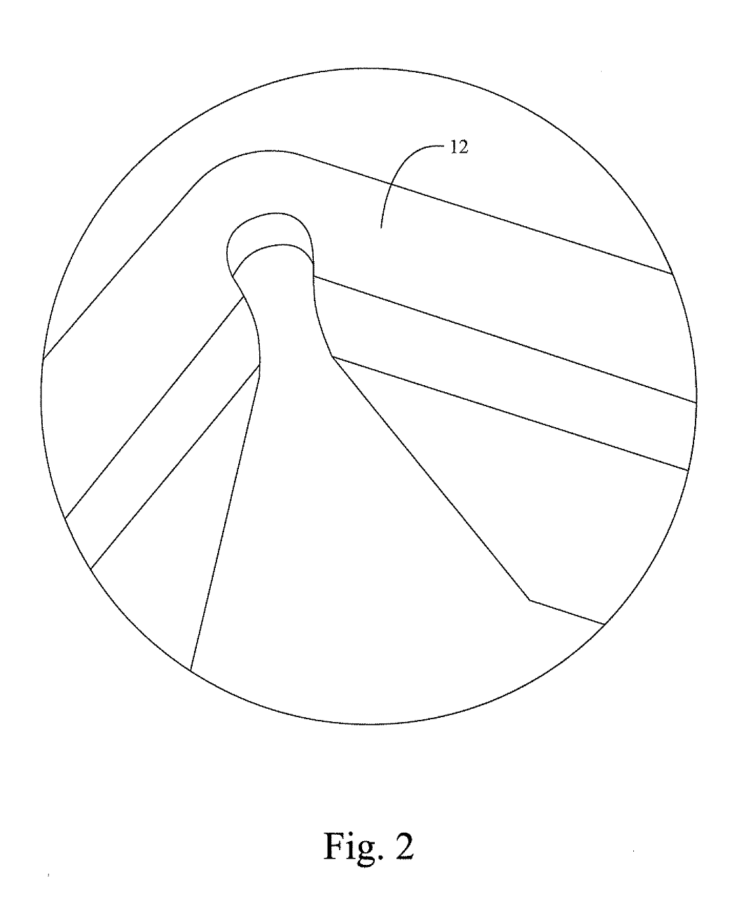

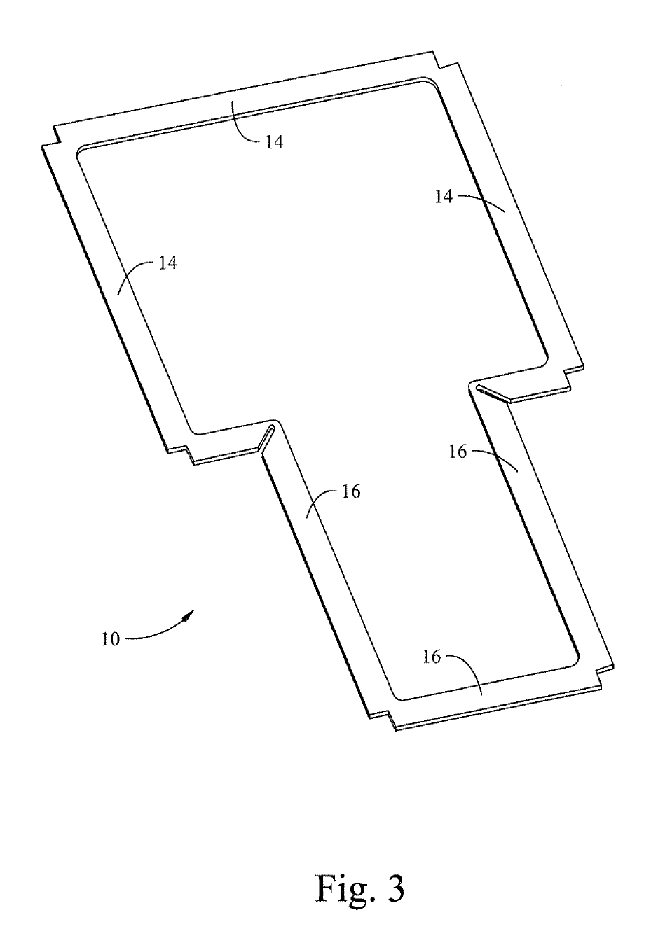

FIGS. 1 through 3 are representative of a conventional method of making a frame for an EMI shielding apparatus. More specifically, FIG. 3 illustrates a flat piece of material 10 that may be formed (e.g., folded, bent, etc.) to make the conventional frame 12 shown in FIGS. 1 and 2. In this conventional method, the piece of material 10 includes a profile for a first frame portion 14 and a second frame portion 16 where the second frame portion 16 is disposed wholly outside the footprint, interior region, or perimeter defined by first frame portion 12.

After recognizing that the conventional method for making a frame has a relatively low material utilization rate, the inventors hereof developed and disclose herein new methods of making frames that have increased material utilization rates (e.g., up to 75%, etc) and reduced the amount of scrap material generated. Accordingly, the inventors' methods allow for reductions in the amount of material needed for making a frame and costs associated therewith. This is accomplished in the exemplary embodiments by using the material inside an interior region or footprint of the first frame portion (which is normally scrapped in conventional methods of manufacturing frames) for one or more other frame portions. For example, the inventors have been able to achieve 45.8% material savings for a 57.3 millimeter×30 mm×1.5 mm frame in one exemplary embodiment.

According to one aspect of the present disclosure, various embodiments of a method are provided for making a frame for an electromagnetic (EMI) shielding apparatus for providing EMI shielding of one or more components. The method includes forming a frame to have a first frame portion, at least a second frame portion that is initially disposed within a footprint of the first frame portion, and at least a portion of a common sidewall shared by and connecting the first frame portion and second frame portion. In the various method embodiments, the second frame portion is repositioned (e.g., formed, folded, bent, rotated, etc.) from its initial position within the footprint of the first frame portion to a second position outside the footprint of the first frame portion. In an exemplary embodiment, the method of forming the frame may include forming the common sidewall to have a bendable hinge portion that connects the second frame portion to the first frame portion, where the hinge portion is bendable to permit the second frame portion to be repositioned outside the footprint of the first frame portion.

According to another aspect of the present disclosure, various embodiments are provided of frames for electromagnetic (EMI) shielding apparatus for providing EMI shielding of one or more components on a substrate. For example, an exemplary embodiment of a frame includes a first frame portion and a second frame portion. The first frame portion has a plurality of sidewalls that at least partially surround an interior region of the first frame portion. The second frame portion is of a size sufficient to fit within the interior region of the first frame portion. The second frame portion also has a plurality of sidewalls. The first and second frame portions share at least a portion of a common sidewall having a bendable hinge portion that connects the first and second frame portions. Exemplary embodiments of frames and methods related thereto are described below.

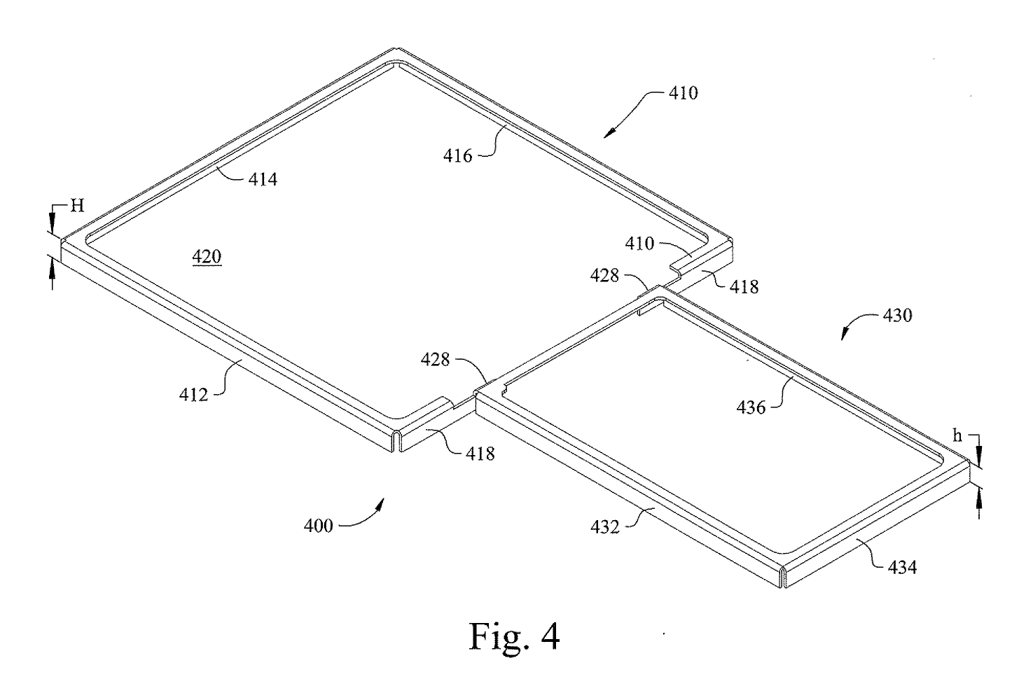

Referring now to the drawings, FIG. 4 shows an exemplary embodiment of a frame 400 for an electromagnetic (EMI) shielding apparatus embodying one or more aspects of the present disclosure. As shown in FIG. 4, the frame 400 includes a first frame portion 410 having a plurality of sidewalls 412, 414, and 416 that at least partially surround an interior region 420 of the first frame portion 410.

The frame 400 further includes a second frame portion 430 of a size sufficient to fit within the interior region 420 of the first frame portion 410. The second frame portion 430 also has a plurality of sidewalls 432, 434, and 436, which have a height h that may be the same as or different from the height H of the sidewalls 412, 414, and 416.

The first and second frame portions 410, 430 share at least a portion of a common sidewall 418 having at least one bendable hinge portion 428 that connects the first and second frame portions 410, 430. The bendable hinge portion 428 permits the second frame portion 430 to be repositioned from an initial, first position within the interior region 420 of the first frame portion 410 to a final, second position outside the footprint of the first frame portion 410. The hinge portion 428 is bendable between a generally straight configuration and a bent configuration, and may be formed in accordance with the methods described below.

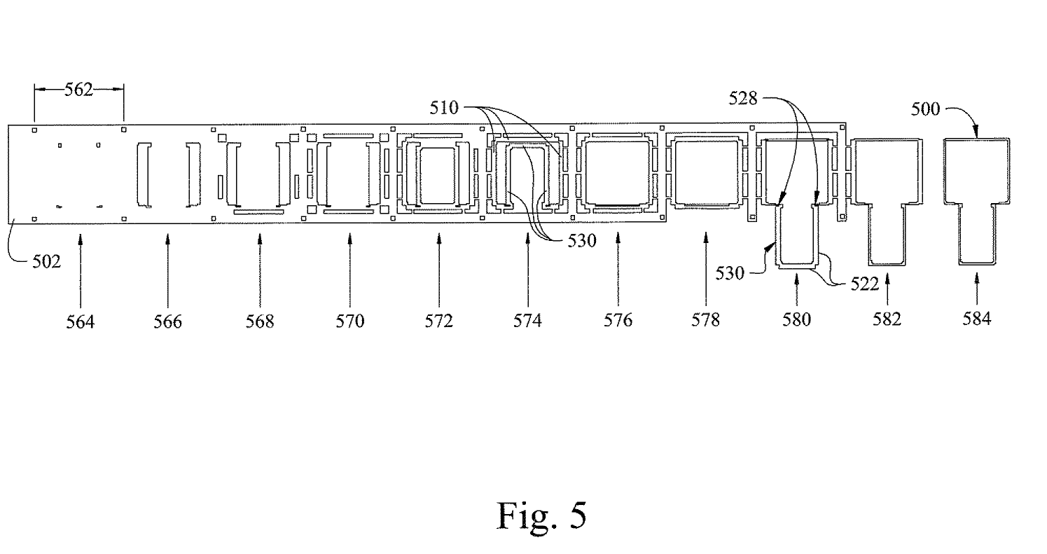

FIGS. 5 through 8 illustrate an exemplary embodiment of a method for making a frame 500 for an electromagnetic (EMI) shielding apparatus using progressive stamping techniques. As shown in FIG. 5, the method generally includes forming a frame 500 through progressive stamping of a strip of metal material 502, which is fed or advanced through numerous operations at stations 562 of a progressive stamping die in a reciprocating stamping press. The method of forming the frame 500 generally includes stamping in a single piece of material 502 a partial profile for a frame 500 that includes a plurality of peripheral walls defining a first frame portion 510 and a second frame portion 530. With each stroke of the reciprocating stamping press, the method provides for iteratively stamping the partial profile for the first frame portion 510 and second frame portion 530, as shown at positions 564 through 574. The profile of the frame is further formed in later die stations 576 through 582. The final station 584 of the progressive die is a cutoff operation that separates the finished frame 500 from the carrying web of the metal material 502.

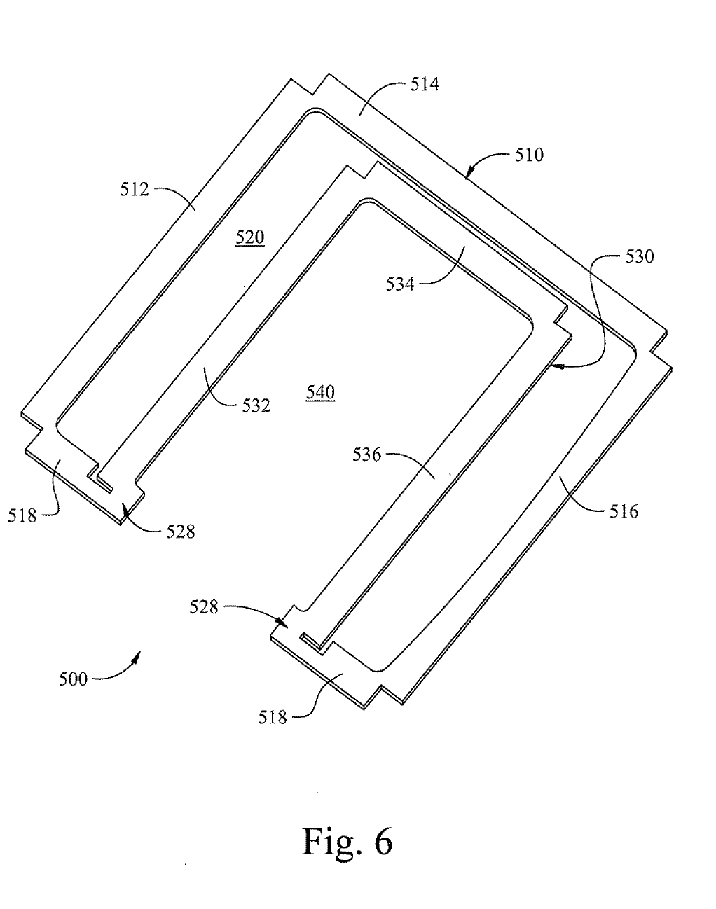

Referring to FIG. 6, the profile of the first frame portion 510 and second frame portion 530 is shown to further illustrate the above method for forming the frame 500. The method for forming the frame 500 includes forming the first frame portion 510 to have a profile for a plurality of sidewalls 512, 514, and 516, which at least partially surround an interior region 520 of the first frame portion 510. Accordingly, the interior region 520 is defined at least in part by the profile for the plurality of sidewalls 512, 514, and 516. The method for forming the frame 500 further includes forming the second frame portion 530 to have a footprint that is disposed within the interior region 520 of the first frame portion 510. As used here, a footprint is defined as the space occupied by the shape and/or outline of a given frame portion. The method of forming the frame 500 includes forming the second frame portion 530 (or a profile thereof) to have a plurality of sidewalls 532, 534, and 536 with an interior region 540.

The method of forming includes forming at least a portion of a common sidewall 518 shared by and connecting the first frame portion 510 and second frame portion 530. The portion of the common sidewall 518 permits the second frame portion 530 to be repositioned outside the footprint (or interior region 520) of the first frame portion 510. Specifically, the method of forming frame 500 preferably includes forming the common sidewall 518 to include a bendable hinge portion 528 that connects the second frame portion 530 to the first frame portion 510. The hinge portion 528 is bendable to permit the second frame portion 530 to be repositioned outside the footprint of the first frame portion 510, as explained below.

Referring back to FIG. 5, the method of forming frame 500 may include stamping the profile of a common sidewall 518 that includes a bendable hinge portion 528. The bendable hinge portion 528 is bendable between a generally straight configuration in which the second frame portion 530 is disposed within the footprint of the first frame portion 510 (at position 574), and a bent configuration in which the second frame portion 530 is repositioned outside the footprint of the first frame portion 510 (at position 580). It should be noted that the method of forming may include repositioning by folding, bending, forming by rotation, etc. the second frame portion 530 in incremental steps, where the second frame portion 530 is bent to an intermediate position (at positions 576 through 578) before the second frame portion 530 is bent to the final bent configuration (shown at positions 580 through 584). Accordingly, the method for forming the frame 500 includes forming the second frame portion 530 in a first initial position disposed within the footprint of the first frame portion 510 before folding, and then repositioning the second frame portion 530 by folding, bending, forming by rotating, etc. the second frame portion 530 from the initial first position (at 574) to the second position (at 580) outside the footprint of the first frame portion 510.

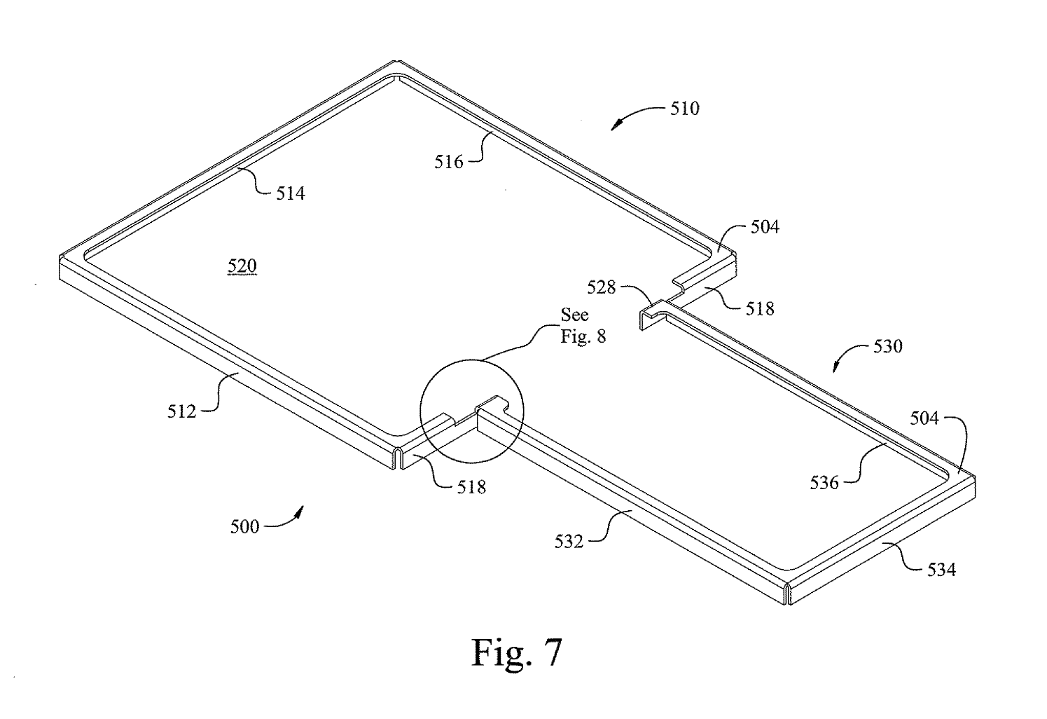

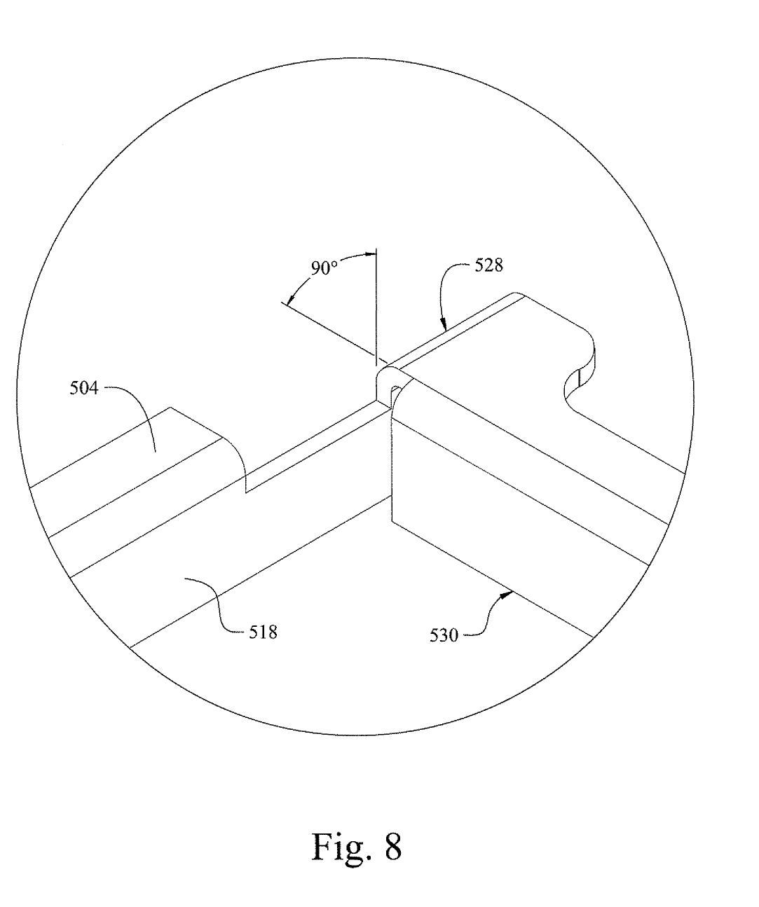

Referring to FIGS. 7 and 8, this example method of forming includes bending the profile to form the common sidewall 518 at an angle of approximately 90 degrees relative to an upper surface 504 of the first frame portion 510. The method further includes forming or bending the bendable hinge portion 528 approximately 90 degrees relative to common sidewall 518. Accordingly, the bendable hinge portion 528 is bent from a generally straight configuration as shown in FIG. 6, to a bent configuration shown in FIGS. 7 and 8, such that the second frame portion 530 is rotated approximately 180 degrees from an initial position relative to the first frame portion 510 (as shown at positions 574 through 580 in FIG. 5). This bending of the bendable hinge portion 528 results in the first frame portion 510 and the second frame portion 530 being generally aligned in a co-planar manner.

Referring back to FIG. 5, the method further includes bending or folding at least a portion 522 of the profile of the second frame portion 530 to form the sidewalls 532, 534, and 536 (shown in FIG. 7). The sidewalls 532, 534, and 536 of the second frame portion 530 are formed at an angle of approximately 90 degrees relative to an upper surface 504 of the second frame portion 530.

The method of forming the frame 500 accordingly comprises forming or folding the second frame portion 530 of the frame profile generally outwardly approximately 180 degrees in a telescopic folding process, to thereby form a second frame portion 530 that is disposed outside of the footprint of the first frame portion 510. The method of forming comprises forming the frame profile to form folded sidewalls 512, 514, 516, 532, 534, and 536, which are generally perpendicular to the upper surface 504 of the frame 500. The method further includes stamping to remove the remaining material connecting the frame 500 to the carrying web of metal material 502.

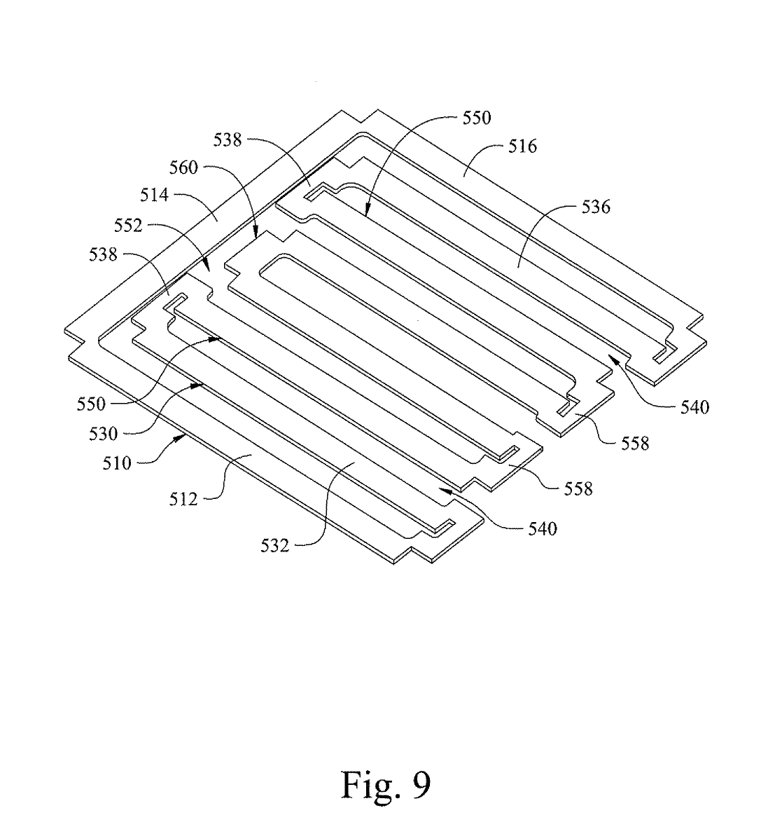

Referring to FIGS. 9 through 11, exemplary embodiments of the method may further include forming a third frame portion 550 having a footprint that is disposed within a second interior region 540 of the second frame portion 530, with at least a portion of a second common sidewall 538 shared by and connecting the second frame portion 530 and third frame portion 550. This example method may further comprise forming a fourth frame portion 560 having a footprint that is disposed within an interior region 552 of the third frame portion 550, with at least a portion of a third common sidewall 558 shared by and connecting the third frame portion 550 and fourth frame portion 560. In such an exemplary method, the fourth frame portion 560 is repositioned outside the footprint of the third frame portion 550.

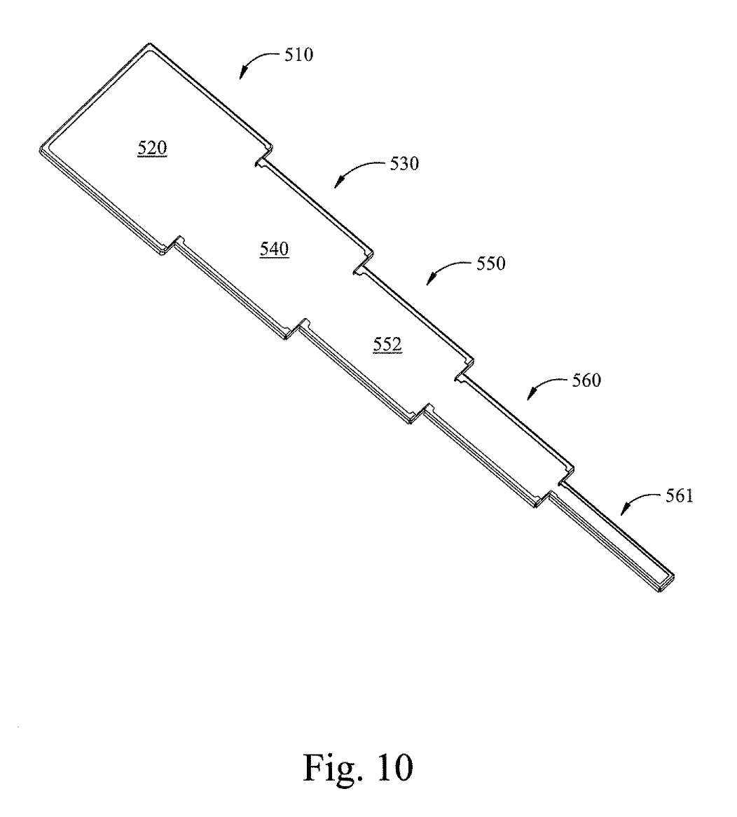

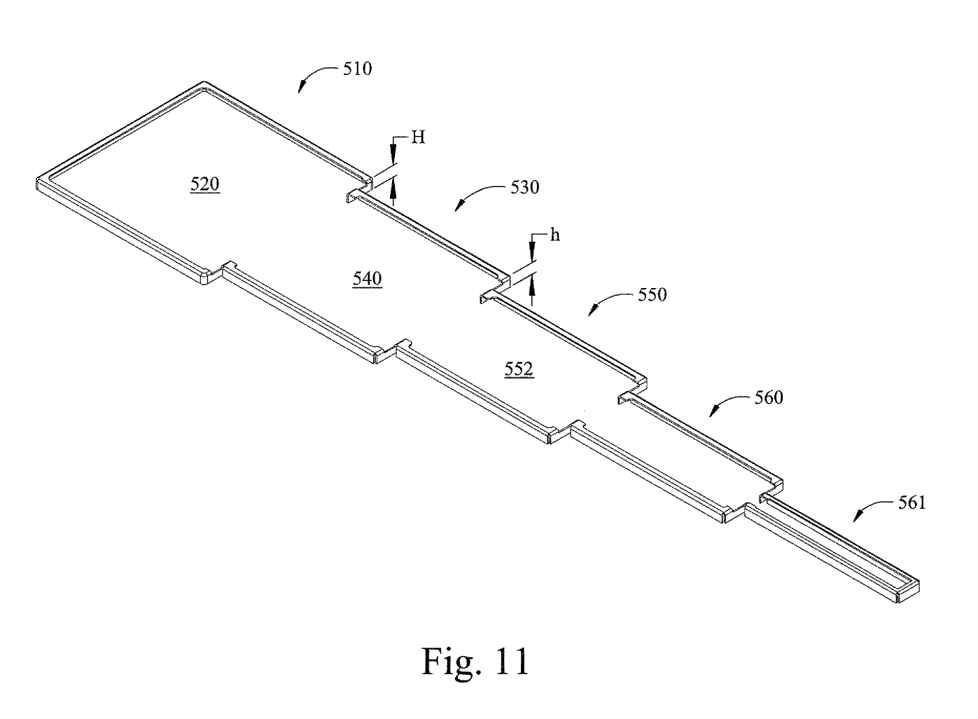

As shown in FIGS. 10 and 11, a fifth frame portion 561 may also be formed and repositioned outside the footprint of the fourth frame portion 560. In this manner, the method of forming a frame may include a telescopic folding process for repositioning interior frame portions outside the footprint of the first frame portion 510, the second frame portion 530, the third frame portion 550, and so on. It should be noted that the sidewalls of the second frame portion 530 may have a height h that may be the same as or different from the height H of the sidewalls of the first frame portion 510.

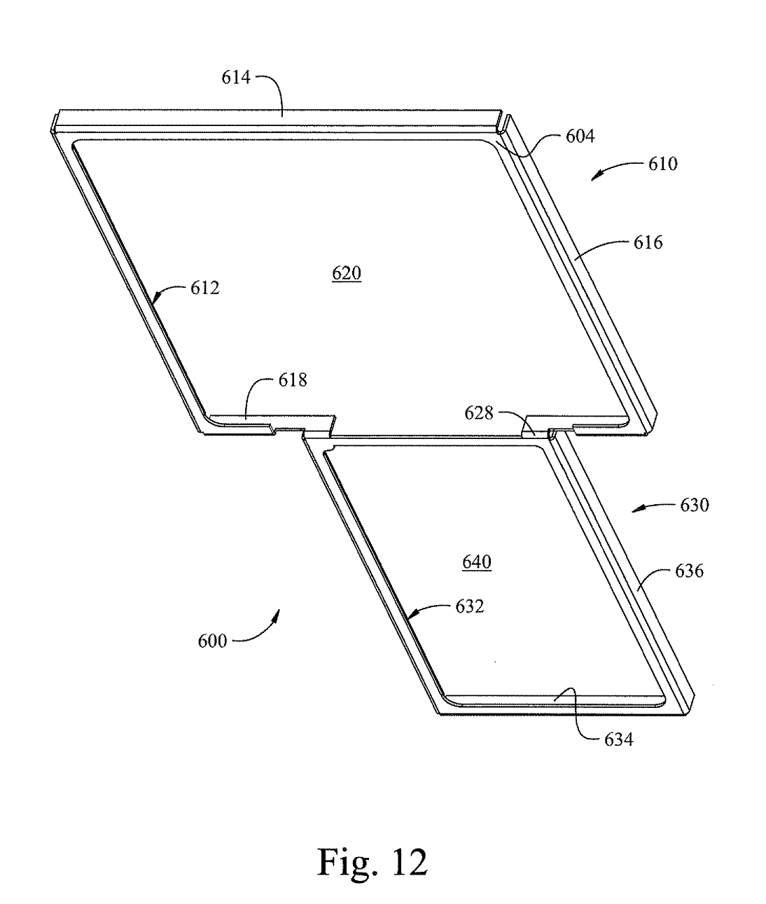

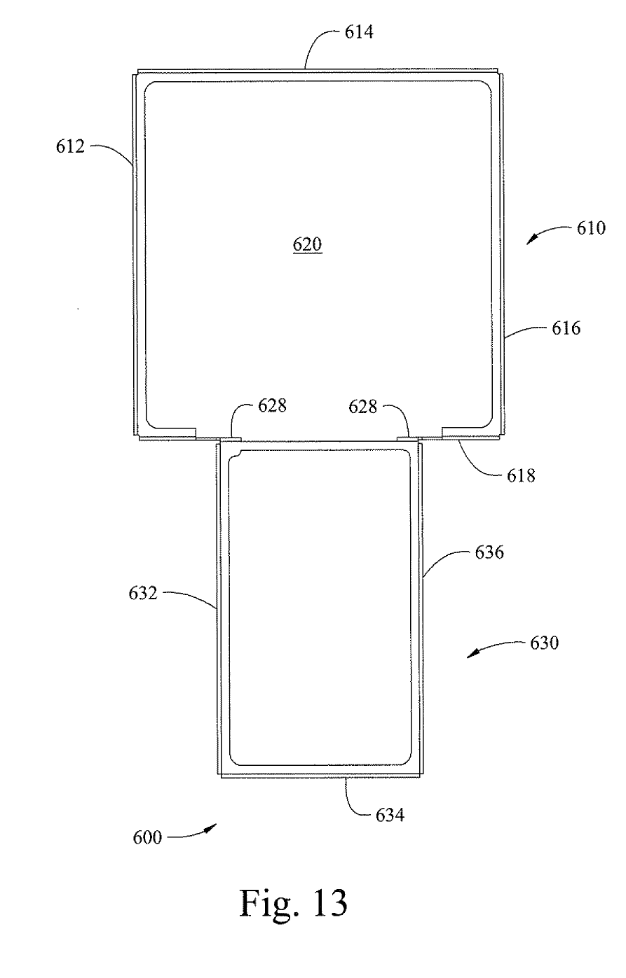

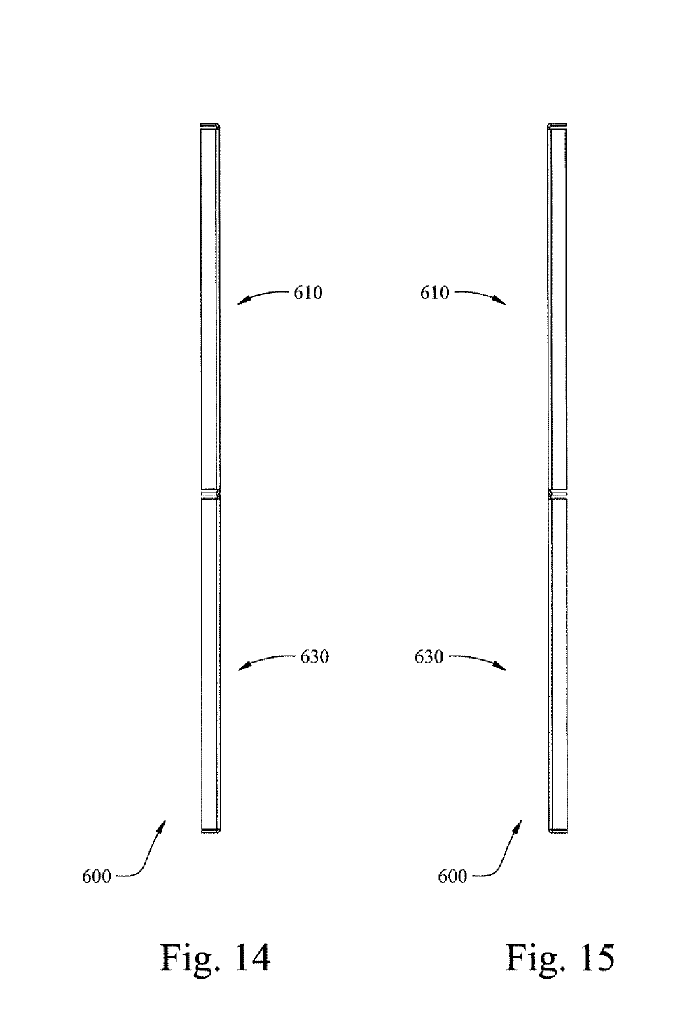

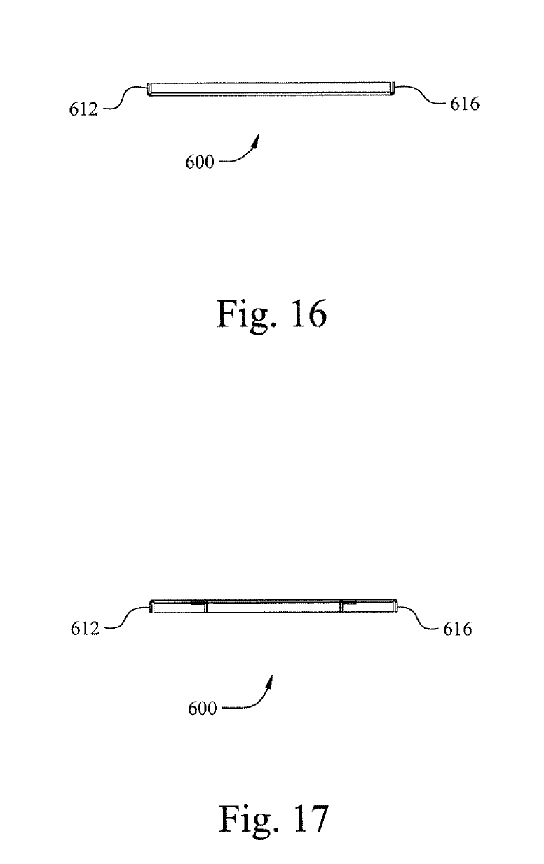

In another aspect of the present disclosure, various embodiments are provided of a frame for an EMI shielding apparatus. Referring to FIGS. 12 through 17, an exemplary embodiment is shown of a frame 600 for an electromagnetic (EMI) shielding apparatus embodying one or more aspects of the present disclosure. The frame 600 for an electromagnetic (EMI) shielding apparatus includes a first frame portion 610 having a plurality of sidewalls 612, 614, and 616 that at least partially surround an interior region 620 of the first frame portion 610. The interior region 620 is defined at least in part by the plurality of sidewalls 612, 614 and 616.

The frame 600 includes a second frame portion 630 of a size sufficient to fit within the interior region 620 defined by the first frame portion 610. In this example, the second frame portion 630 has a footprint of a size sufficient to fit within the interior region 620 of the first frame portion 610. The second frame portion 630 has a plurality of sidewalls 632, 634, and 636. The first and second frame portions 610, 630 share at least a portion of a common sidewall 618 having a bendable hinge portion 628 that connects the second frame portion 630 to the first frame portion 610.

With further reference to FIG. 12, the bendable hinge portion 628 is bendable between a generally straight configuration and a bent configuration. The second frame portion 630 is of a size sufficient to fit within the interior region 620 when the bendable hinge portion 628 is in the generally straight configuration. When the bendable hinge portion 628 is in the bent configuration (as shown in FIG. 12), the second frame portion 630 is disposed outside of the footprint of the first frame portion 610. And, the first frame portion 610 and the second frame portion 630 are generally aligned in a co-planar manner. The plurality of sidewalls of the first frame portion 610 comprise at least three sidewall portions 612, 614 and 616, which at least partially surround a generally rectangular interior region 620 partially enclosed by the first frame portion 610. The plurality of sidewalls of the second frame portion 630 comprise at least three sidewall portions 632, 634 and 636 partially surrounding a second rectangular region 640. The sidewall portions 612, 614, 616, 632, 634 and 636 are formed at an angle of approximately 90 degrees relative to an upper surface 604 of the frame 600. Alternative embodiments may include frame portions having a different number of sidewalls (e.g., more than three, etc.) and/or in different shapes (e.g., non-rectangular, etc.).

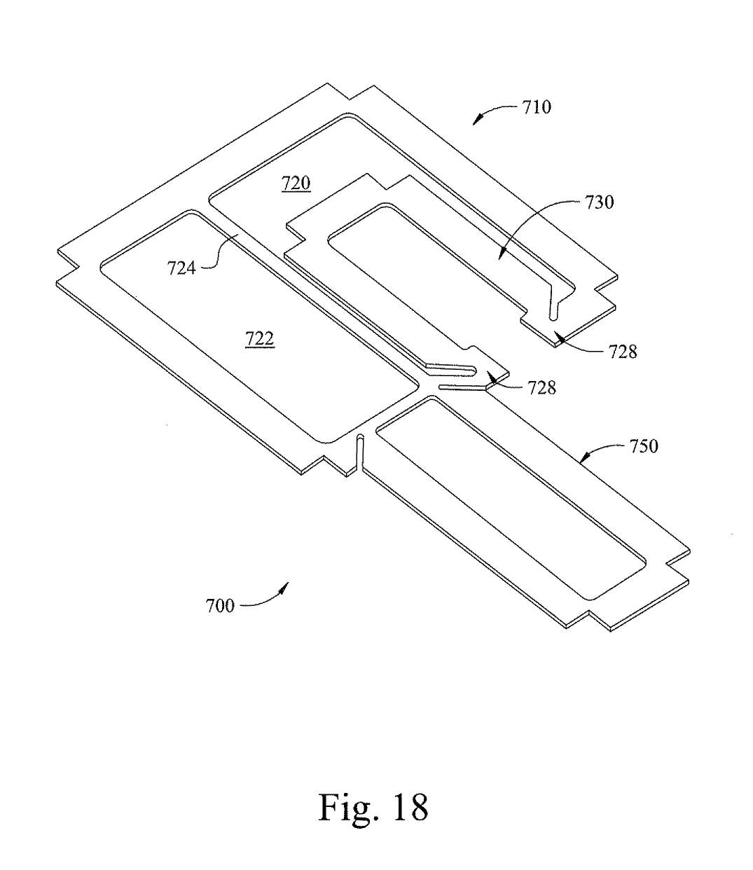

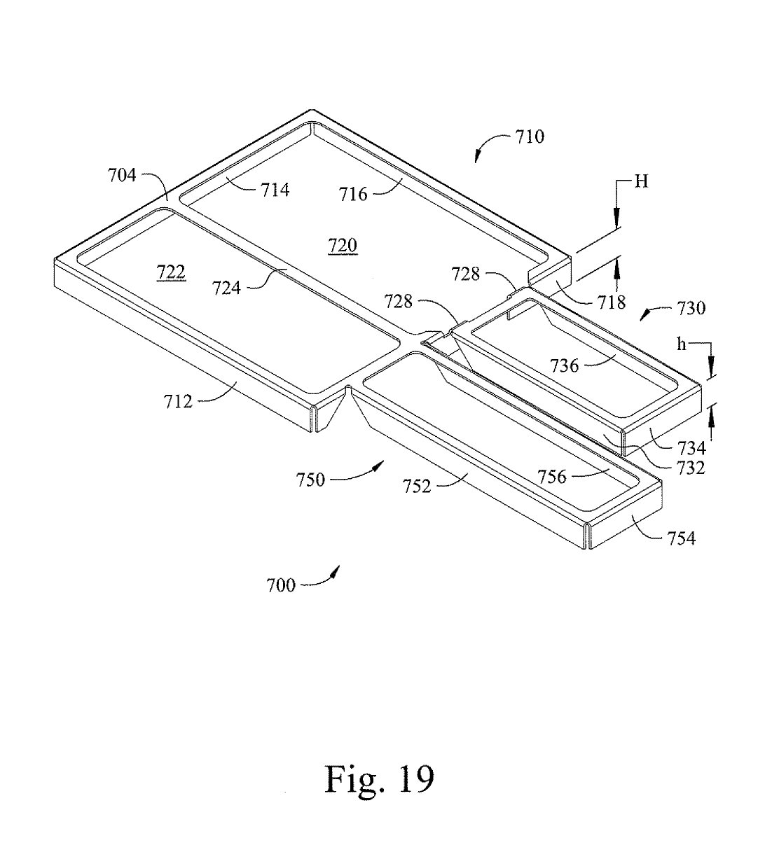

Referring to FIGS. 18 and 19, another exemplary embodiment of a frame 700 for an electromagnetic (EMI) shielding apparatus is shown. As shown in FIG. 18, there is a first frame portion 710 having a profile for a plurality of sidewalls that at least partially surround an interior region 720 of the first frame portion 710. At least part of the interior region 720 is defined at least in part by the profile for the plurality of sidewalls (e.g., walls 714 and 716 shown in FIG. 19, etc.). In this exemplary embodiment, the first frame portion 710 further includes a second interior region 722 that is defined at least in part by a web 724 depending from upper surface 704, and one or more sidewalls (e.g., walls 712 and 714, etc.).

The frame 700 includes a second frame portion 730 of a size sufficient to fit within the interior region 720 defined by the first frame portion 710. In this example, the second frame portion 730 has a footprint of a size sufficient to fit within the interior region 720 of the first frame portion 710. The second frame portion 730 has a plurality of sidewalls 732, 734, and 736.

The first and second frame portions 710, 730 share at least a portion of a common sidewall 718 having a bendable hinge portion 728 that connects the second frame portion 730 to the first frame portion 710. The sidewalls 732, 734 and 736 of the second frame portion 730 have a height h that may be different from (or the same as) the height H of the sidewalls 712, 714 and 716 of the first frame portion 710. The profile for the frame 700 shown in FIG. 18 further includes a third frame portion 750 depending from the first frame portion 710, which profile is formed to provide a plurality of sidewalls 752, 754, and 756 of the third frame portion 750.

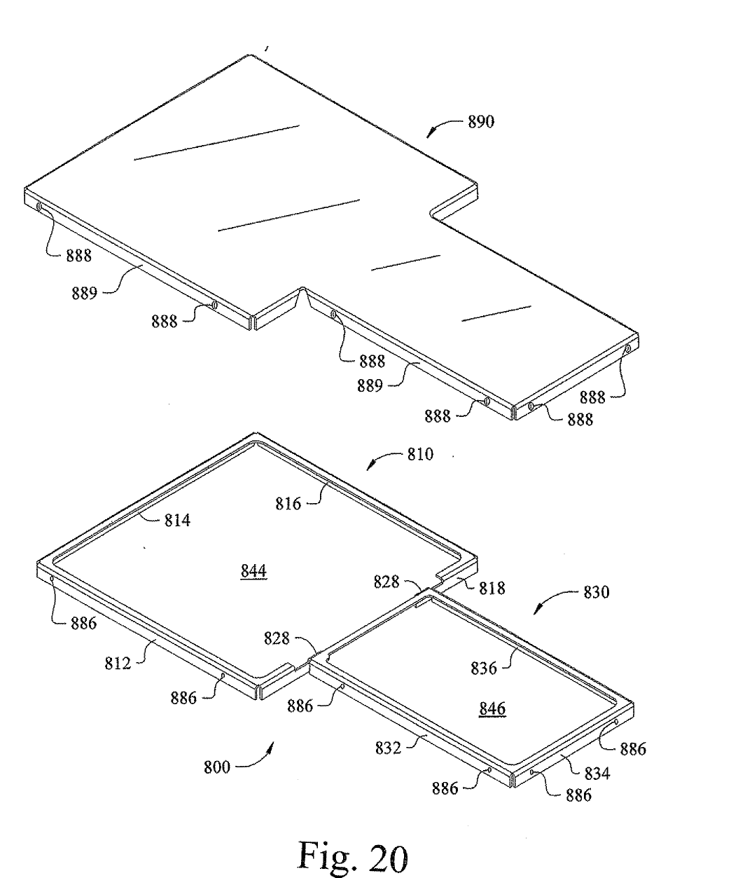

In another aspect of the present disclosure, methods relating to providing electromagnetic interference (EMI) shielding for one or more components on a substrate are provided. Referring to FIGS. 20 through 22, an exemplary method for providing electromagnetic interference (EMI) shielding for one or more components includes forming a frame 800 having a first frame portion 810 and a second frame portion 830 disposed within a footprint of the first frame portion 810. A common sidewall 818 is shared by and connects the first and second frame portions 810, 830. The second frame portion 830 is repositioned outside the footprint of the first frame portion 810.

This example method for providing electromagnetic interference (EMI) shielding further includes attaching at least one cover 890 to the frame 800. When the at least one cover 890 is attached to the frame 800, the cover 890, first frame portion 810, and second frame portion 830 cooperatively define first and second EMI shielding compartment 844, 846 depending from and on opposite sides of the shared common sidewall 818. The common sidewall 818 may formed to include a bendable hinge portion 828.

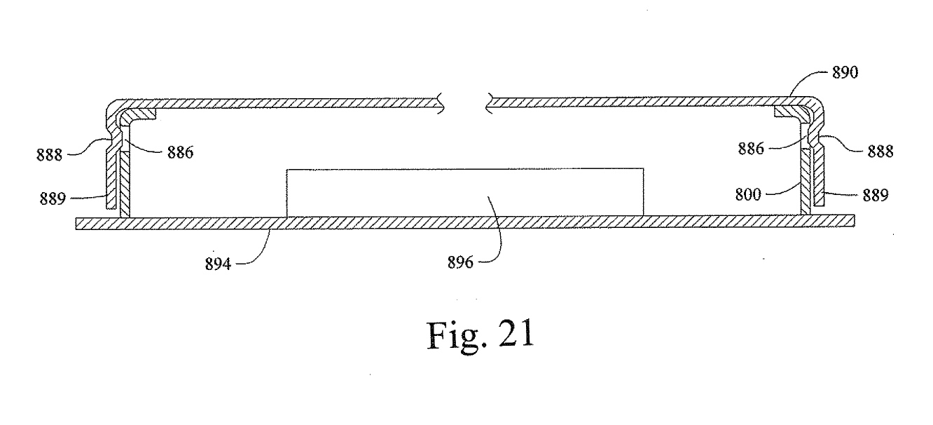

As shown in FIG. 21, this example method for providing electromagnetic interference (EMI) shielding may further include positioning the frame 800 and attached cover 890 relative to a substrate 894 (e.g., printed circuit board, etc.). For example, the frame 800 may be mechanically attached (e.g., soldered, etc.) to the substrate 894. Accordingly, the EMI shielding apparatus may thus provide EMI shielding to one or more electrical components 896 on the substrate 894 that are positioned within the EMI shielding compartments 844, 846.

The cover 890 can be removably attached to the frame 800. As shown in FIGS. 20 and 21, one or more of the frame's sidewalls 812, 814, 816, 832, 834, and 836 include one or more openings 886 for receiving corresponding inwardly extending dimples 888 of the cover 890. In this particular embodiment, one or more of the frame's sidewalls 812, 814, 816, 832, 834, and 836 include at least two circular openings 886. Alternative embodiments may include more or less than two openings 886 (and in some cases no openings) in the frame sidewall, and/or openings that do not extend completely through the sidewalls. Plus, each of the frame's sidewalls does not need to include the same number of openings 886 as the other sidewalls of the frame 800.

The cover 890 includes edge portions 889 extending downwardly from the top of the cover 890. The edge portions 889 include detents, protrusions, dimples, etc. 888 configured to be engagingly received in the openings 886 in the frame's sidewalls. In this embodiment, the cover 890 can have more or less than two dimples 888 (and in some cases no dimples) on each of the cover's edge portions 889, and each cover edge portion 889 does not need to include the same number of dimples 888 as the cover's other edge portions 889. The cover's edge portions 889 may flex outwardly and/or the frame's sidewalls 812, 814, 816, 832, 834, and 836 may flex inwardly as the dimples 888 are slid over the corresponding sidewalls of the frame for engaging the openings 886. In this exemplary manner, the cover 890 can thus be releasably retained to the frame 800 by the engagement of the dimples 888 within the openings 886 in the frame's sidewalls 812, 814, 816, 832, 834, and 836. This, in turn, provides an EMI shield apparatus having a cover 890 that may be readily removed from the frame 800, for example, to allow access to components under the cover 890. The cover 890 may subsequently be reattached to the frame 800, or a new cover may be assembled onto the frame 800. Accordingly, various embodiments of the present disclosure can help avoid the access problems associated with soldered shields by providing shields that can be readily opened when repair work is necessary or desired.

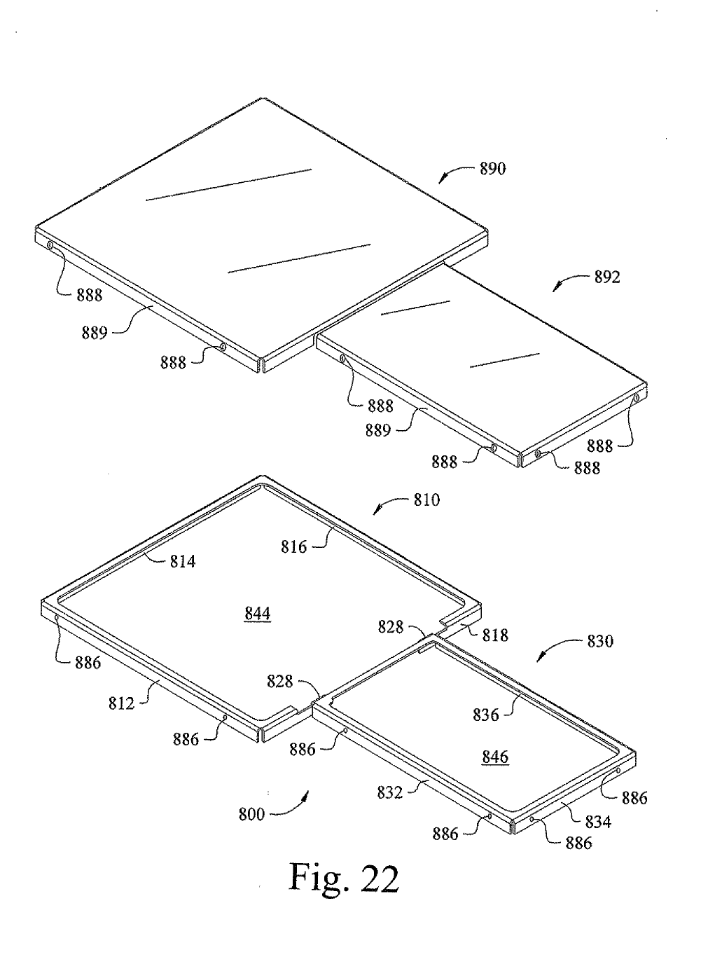

FIG. 22 illustrates an alternative exemplary embodiment of an EMI shielding apparatus in which two covers 890, 892 are attachable to the frame 800. In such embodiment, the method for providing electromagnetic interference (EMI) shielding may comprise attaching the first cover 890 to the first frame portion 810 such that the first cover 890 and first frame portion 810 cooperatively define at least a first EMI shielding compartment 844. A second cover 892 may be attached to the second frame portion 830 such that the second cover 892 and second frame portion 830 cooperatively define at least a second EMI shielding compartment 846. The first EMI shielding compartment 844 may be separated from the second EMI shielding compartment 846 by the shared common sidewall 818 disposed between the two EMI shielding compartments 844, 846. As shown in FIG. 21 and explained above, the frame 800 with the covers 890, 892 attached thereto may further be used in combination with electrical components 896 and a substrate 894 (e.g., printed circuit board, etc.). For example, the frame 800 with the covers 890, 892 attached thereto may be mechanically attached to the substrate 894.

With continued reference to FIG. 22, one or more of the frame's sidewalls 812, 814, 816, 832, 834 and 836 include one or more openings 886 for receiving corresponding dimples 888 of the first cover 890 and second cover 892, which can be removably attached to the frame 800. The first cover 890 and second cover 892 include edge portions 889 extending downwardly from the top of the cover. The edge portions 889 include detents, protrusions, or dimples 888 configured to be engagingly received in the openings 886 in the frame's sidewalls. In this exemplary embodiment, the first cover 890 and second cover 892 can have more or less than two dimples 888 (and in some cases no dimples) on each of the edge portions 889, and each edge portion 889 does not need to include the same number of dimples 888 as other edge portions 889. The edge portions 889 of the first and second covers 890, 892 may flex outwardly and/or the frame's sidewalls 812, 814, 816, 832, 834 and 836 may flex inwardly as the dimples 888 are slid over the frame's sidewalls for engaging the openings 886. In this exemplary manner, the first cover 890 and second cover 892 may thus be releasably retained to the frame 800 by the engagement of the dimples 888 within the openings 886.

A non-exhaustive list will now be provided of exemplary materials from which a frame for an EMI shielding apparatus may be made according to the present disclosure. Exemplary materials include cold rolled steel, nickel-silver alloys, copper-nickel alloys, stainless steel, tin-plated cold rolled steel, tin-plated copper alloys, carbon steel, brass, copper, aluminum, copper-beryllium alloys, phosphor bronze, steel, alloys thereof, or any other suitable electrically-conductive and/or magnetic materials. In one exemplary embodiment, a frame for an EMI shielding apparatus is from a sheet of nickel-silver alloy having a thickness of about 0.20 millimeters. The materials and dimensions provided herein are for purposes of illustration only, as a frame for an EMI shielding apparatus may be configured from different materials and/or have different dimensions depending, for example, on the particular application, such as the components to be shielded, space considerations within the overall device, EMI shielding and heat dissipation needs, and other factors.

Numerical dimensions and values are provided herein for illustrative purposes only. The particular dimensions and values provided are not intended to limit the scope of the present disclosure.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter. The disclosure of a first value and a second value for a given parameter can be interpreted as disclosing that any value between the first and second values could also be employed for the given parameter. Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A method of making a frame for an electromagnetic (EMI) shielding apparatus for use in providing EMI shielding for one or more components on a substrate, the method comprising:
forming a frame to have at least a first frame portion, a second frame portion, and a common sidewall including at least a portion shared by and connecting the first and second frame portions, whereby the second frame portion is repositioned from being disposed within a footprint of the first frame portion to outside the footprint of the first frame portion.

2. The method of claim 1, wherein forming includes:
forming the second frame portion to have a first initial position disposed within the footprint of the first frame portion; and
then folding, bending or forming by rotating the second frame portion from the first initial position within the footprint of the first frame portion to a second position in which the second frame portion is outside the footprint of the first frame portion.

3. The method of claim 1, wherein forming includes forming the first frame portion to include a plurality of sidewalls that define the footprint and that at least partially surround an interior region of the first frame portion in which the second frame portion is initially disposed before the second frame portion is repositioned outside the footprint of the first frame portion.

4. The method of claim 3, wherein the interior region is defined at least in part by the plurality of sidewalls of the first frame portion.

5. The method of claim 3, wherein forming includes forming the second frame portion to have a footprint that is disposed within the interior region of the first frame portion.

6. The method of claim 1, wherein forming includes forming the common sidewall to have a bendable hinge portion that connects the second frame portion to the first frame portion, the bendable hinge portion being bendable to permit the second frame portion to be repositioned outside the footprint of the first frame portion.

7. The method of claim 6, wherein the bendable hinge portion is bendable between a generally straight configuration in which the second frame portion is disposed within the footprint of the first frame portion, and a bent configuration in which the second frame portion is repositioned outside the footprint of the first frame portion.

8. The method of claim 6, wherein forming includes bending the bendable hinge portion and rotating the second frame portion approximately 180 degrees relative to the first frame portion, such that the first frame portion and the second frame portion are generally aligned in a co-planar manner.

9. The method of claim 1, wherein forming includes folding at least a portion of the common sidewall approximately 90 degrees relative to an upper surface of the first and second frame portions, such that the first and second frame portions share the common sidewall with a bendable hinge portion that connects the second frame portion to the first frame portion.

10. The method of claim 1, wherein forming includes stamping a profile for the first and second frame portions in a single piece of material, and then folding the stamped piece of material.

11. The method of claim 1, wherein forming includes forming a third frame portion having a footprint that is disposed within an interior region of the second frame portion, with at least a portion of a second common sidewall shared by and connecting the second frame portion and third frame portion, whereby the third frame portion is repositioned such that the footprint of the third frame portion is outside the interior region of the second frame portion.

12. The method of claim 11, wherein forming includes a telescopic folding process for repositioning interior frame portions outside the footprint of at least the first frame portion.

13. A method relating to providing electromagnetic interference (EMI) shielding for one or more components on a substrate, the method comprising:
forming a piece of material having a first frame portion and a second frame portion initially disposed within a footprint of the first frame portion with a common sidewall portion shared by and connecting the first and second frame portions, whereby the second frame portion is repositioned outside the footprint of the first frame portion; and
attaching at least one cover to at least one of the first and second frame portions.

14. The method of claim 13, wherein attaching at least one cover to at least one the first and second frame portions comprises attaching a cover to the first and second frame portions such that the cover, and the first and second frame portions cooperatively define first and second EMI shielding compartments depending from the shared common sidewall portion.

15. The method of claim 13, further comprising positioning the first and second frame portions and cover attached thereto relative to a substrate to provide EMI shielding to one or more components on the substrate.

16. The method of claim 13, wherein attaching at least one cover to at least one of the first and second frame portions comprises:
attaching a first cover to the first frame portion such that the first cover, first frame portion, and shared common sidewall portion cooperatively define at least a first EMI shielding compartment; and
attaching a second cover to the second frame portion such that the second cover, second frame portion, and shared common sidewall portion cooperatively define at least a second EMI shielding compartment.

17. A frame for an electromagnetic (EMI) shielding apparatus for use in providing EMI shielding for one or more components on a substrate, the frame comprising:
a first frame portion having a plurality of sidewalls that at least partially surround an interior region of the first frame portion;
a second frame portion of a size sufficient to fit within the interior region defined by the first frame portion, the second frame portion having a plurality of sidewalls,
wherein the first and second frame portions share at least a portion of a common sidewall having a bendable hinge portion that connects the second frame portion to the first frame portion.

18. The frame of claim 17, wherein the second frame portion has a footprint of a size sufficient to fit within the interior region of the first frame portion.

19. The frame of claim 17, wherein:
the bendable hinge portion is bendable between a generally straight configuration and a bent configuration;
the second frame portion is of a size sufficient to fit within the interior region when the bendable hinge portion is in the generally straight configuration; and
the second frame portion is disposed outside of the footprint of the first frame portion when the bendable hinge portion is in the bent configuration, such that the first frame portion and the second frame portion are generally aligned in a co-planar manner.

20. The frame of claim 17, wherein:
the plurality of sidewalls of the first frame portion comprise at least three sidewall portions that at least partially surround a generally rectangular interior region that is partially enclosed by the first frame portion;
the plurality of sidewalls of the second frame portion comprise at least three sidewall portions; and
the second frame portion is of a size sufficient to fit within the generally rectangular interior region of the first frame portion.

21. An EMI shielding apparatus including the frame of claim 17 and at least one cover attached to the frame such that the cover and frame cooperatively define at least one EMI shielding compartments.

22. An EMI shielding apparatus including the frame of claim 17, and further comprising:
a first cover attached to the first frame portion such that the first cover and first frame portion cooperatively define at least a first EMI shielding compartment; and
a second cover attached to the second frame portion such that the second cover and second frame portion cooperatively define at least a second EMI shielding compartment separated from the first EMI shielding compartment by the shared common sidewall portion.

23. An electrical device including a printed circuit board and the frame of claim 17 mechanically attached to the printed circuit board.
